(19) United States
(12) Patent Application Publication
(10) Pub. No.: US 2024/0276660 A1
(43) Pub. Date: Aug. 15, 2024

(54) COATINGS FOR GALVANIC CORROSION MITIGATION

(71) Applicant: Apple Inc., Cupertino, CA (US)

(72) Inventors: Isabel Yang, San Jose, CA (US); Todd S. Mintz, San Jose, CA (US); James A. Curran, Sunnyvale, CA (US); Timothy D. Burks, Santa Cruz, CA (US); Harshal U. Shinde, San Jose, CA (US)

(21) Appl. No.: 18/423,800

(22) Filed: Jan. 26, 2024

Related U.S. Application Data
(60) Provisional application No. 63/485,205, filed on Feb. 15, 2023.

(51) Int. Cl. H05K 5/02; C23C 14/12; C25D 13/14; H05K 5/04

(52) U.S. Cl. CPC H05K 5/0217; C23C 14/12; C25D 13/14; H05K 5/04

(57) ABSTRACT

To eliminate galvanic corrosion, a housing includes a clad. The clad includes an interior metal disposed within an exterior metal and a clad interface. The exterior metal includes a lower electrical conductivity potential than the interior metal. An aperture can extend through the exterior metal and the clad interface and an actuator or a plug can be disposed within the aperture. The housing further includes a corrosion resistant coating disposed on a portion of the interior metal at the clad interface. The corrosion resistant coating can include a thickness between about 2 μm and about 10 μm.

### CROSS-REFERENCE TO RELATED APPLICATION(S)

This claims priority to U.S. Provisional Patent Application No. 63/485,205, filed 15 Feb. 2023, and entitled “Coatings for Galvanic Corrosion Mitigation,” the entire disclosure of which is incorporated by reference in its entirety.

### FIELD

The described embodiments relate generally to materials for housings, structures, and/or electronic devices. More particularly, the present embodiments relate to eliminating or preventing galvanic corrosion of clad parts.

### BACKGROUND

Technology related to the use of dissimilar materials has become increasingly widespread throughout various industries and applications, including the portable computing and electronic device industries. For example, a housing for an electronic device can include a metal clad material having a lightweight interior metal within a more durable exterior metal. Since the weight of the device is important to consumers, it is desirable to have the clad material be mostly the lightweight material with a thin exterior shell of durable material.

However, one difficulty in the use of dissimilar metals is galvanic corrosion. Galvanic corrosion is induced due to the difference in potentials of different metal materials when brought into contact with an electrolyte (e.g., water). In such an environment, a corrosive current is generated. When galvanic corrosion occurs, the strength of the contact points between the dissimilar metal materials weakens or the components of the clad material corrode.

### SUMMARY

According to some examples, a housing for an electronic device can include a clad material. The clad material can include an interior metal disposed within an exterior metal. In some examples, the exterior metal can include a lower electrical conductivity than the interior metal. The housing can further include a clad interface. The housing can define an aperture extending through the exterior metal and the clad interface. An actuator or a plug can be disposed within the aperture. A corrosion resistant coating can be disposed on the interior metal. The coating can include a thickness between about 1 μm and about 10 μm.

In some examples, the actuator can include at least one of a button, a speaker, a switch. The exterior metal can include stainless steel or titanium, and the interior metal can include aluminum. In some examples, the exterior metal can be substantially free of the corrosion resistant coating. In some examples, the corrosion resistant coating includes a parylene. In some examples, the corrosion resistant coating can include an electrophoretic deposition. In other examples, the corrosion resistant coating can include a vapor deposition.

According to some examples, a method of forming a protective interface in a housing can include having a clad interface disposed between an exterior metal and an interior metal. The exterior metal can include an outer surface and an inner surface. The method can include applying a corrosion resistant coating to a portion of the interior metal that contacts the exterior metal. In some examples, applying a corrosion resistant coating can include a chemical vapor deposition process. In other examples, applying a corrosion resistant coating can include a physical vapor deposition process. In some examples, applying a corrosion resistant coating includes a vapor deposition polymerization process. The exterior metal can include stainless steel or titanium, and the interior metal can include aluminum.

In some examples, the corrosion resistant coating is a first coating and the method further includes applying a second coating to at least a portion of the interior metal. The first coating and the second coating can include different compositions. In some examples, the method further includes masking the exterior metal prior to applying the corrosion resistant coating to the interior metal. Masking the exterior metal can include applying a removable coating to the exterior metal.

According to some examples, a system configured to prevent galvanic corrosion of a housing can include a clad structure having an exterior metal and an interior metal joined at an interface. In some examples, the interior metal includes a metal more susceptible to corrosion than the exterior metal. The system further includes a corrosion resistant coating disposed on the interior metal. In some examples, the corrosion resistant coating can be temperature resistant up to about 120° C. In some examples, the corrosion resistant coating includes a thickness between about 1 μm and about 10 μm. In some examples the coating can include a polyurethane.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a perspective view of an electronic device having a housing.

FIG. 2A illustrates a cross sectional view of a portion of an electronic device.

FIGS. 2B-2C illustrate a cross sectional view of a portion of an electronic device showing an interior metal susceptible to galvanic corrosion.

FIG. 3A illustrates a cross sectional view of a clad material having an interior metal disposed within an exterior metal.

FIG. 3B illustrates the clad material of FIG. 3A with a corrosion resistant coating disposed on the interior metal.

FIG. 3C illustrates clad material of FIG. 3A with a first corrosion resistant coating and a second corrosion resistant coating disposed on the interior metal.

FIG. 4 illustrates an example clad structure having a complicated geometry and at least one aperture.

FIG. 5 illustrates a method of forming a protective interface in a housing.

### DETAILED DESCRIPTION

Reference will now be made to examples illustrated in the accompanying drawings. The following descriptions are not intended to limit the embodiments to one preferred example. Rather, they are intended to cover alternatives, modifications, and equivalents that can be included within the spirit and scope of the described embodiments as defined by the appended claims.

The following disclosure relates to a system that provides protection to a clad substrate from galvanic corrosion. In some examples, an electronic device can include a housing made of a clad material. In other words, the housing can include an exterior metal and an interior metal that is different from the exterior metal. When the electronic device having such a configuration is exposed to an electrolyte such as seawater, rainwater, sweat, or any other ingress of water from the outside, the water may penetrate between openings on the exterior of the device and cause galvanic corrosion of the interior metal.

In a particular embodiment, the exterior metal can include a metal that is more corrosion resistant than the interior metal. In other words, the exterior metal can include a metal less susceptible to corrosion than the interior metal. As such, one way to prevent galvanic corrosion is to ensure that only the exterior metal is exposed to an electrolyte (e.g., water) and the interior metal is kept interior to the device in a watertight configuration. Generally, the exterior metal can be heavier than the interior metal. Thus, having the interface between the exterior metal and interior metal further away from the exterior surface of the device can result in a heavier device. In some embodiments, the weight reduction benefits can be achieved by having a thin exterior metal shell while protecting the interior metal from the electrolyte in openings and susceptible regions by protecting the interior metal with a corrosion resistant coating applied to the interior metal and the interface between the exterior metal and interior metal at the susceptible regions.

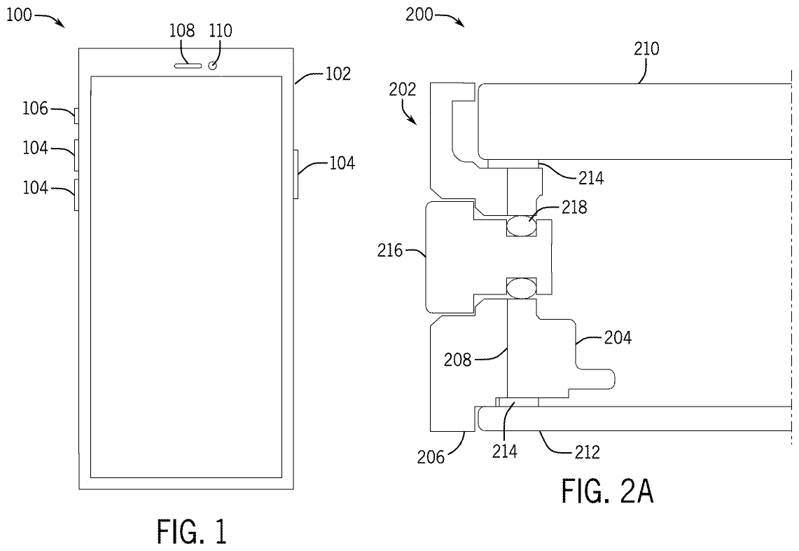

These and other embodiments are discussed below with reference to FIGS. 1-5. However, those skilled in the art will readily appreciate that the detailed description given herein with respect to these Figures is for explanatory purposes only and should not be construed as limiting. Furthermore, as used herein, a system, a method, an article, a component, a feature, or a sub-feature including at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1 illustrates a perspective view of an electronic device having a housing that can include the systems and techniques described herein, in accordance with some embodiments. FIG. 1 illustrates a smartphone 100. However, the systems and techniques described herein are not limited to a particular device, but can be included in any suitable device (e.g. a phone, tablet computer, smart watch, portable computer, etc.). According to some examples, the housing 102 can include a clad material. As discussed above, in some embodiments, the housing 102 can include several openings and/or interfaces susceptible to an electrolyte (e.g. water, sweat, etc.) penetrating the exterior of the housing and causing corrosion to an interior metal and/or interior components. For example, as shown in FIG. 1, the housing 102 can include at least one button 104, a switch 106, a speaker 108, a camera interface 110, and the like.

In some examples, the housing 102 can include two metals that make up the clad material. The exterior metal can include a metal less susceptible to corrosion than the interior metal. In some examples, the exterior metal can be harder, more durable, and often heavier than the interior metal. The exterior metal can include a generally corrosion resistant metal (e.g. a high strength stainless steel, titanium, etc.) and the interior metal can include a metal more susceptible to galvanic corrosion that can be lighter in weight (e.g. aluminum, aluminum alloy, magnesium, magnesium alloy, beryllium, beryllium alloy, etc.) than the exterior metal. The exterior metal and the interior metal can include electrochemically dissimilar metals. Galvanic corrosion refers to corrosion damage that occurs when two different metals are in electrical contact in the presence of an electrolyte, where the more noble metal is protected and the more active metal tends to corrode. In other words, in addition to environmental salinity, the severity of galvanic corrosion that occurs when two metals come into contact is dependent on the dissimilarity of the two participating metals and the magnitude of the electrical conductivity between each metal. The algebraic difference between the electrode potentials of the two metals can determine the driving force of galvanic corrosion. The metal with a lower electrochemical potential acts as the anode in an aqueous environment. In most assemblies with other metals, aluminum will be the anode of the resulting galvanic cell, and hence, likely to suffer galvanic corrosion.

In practice, a tension exists between the exterior metal and the interior metal because an increase in the outer metal typically means added durability and weight to the device, while an increase in the interior metal results in a device having a lighter weight, but an added susceptibility to the galvanic corrosion.

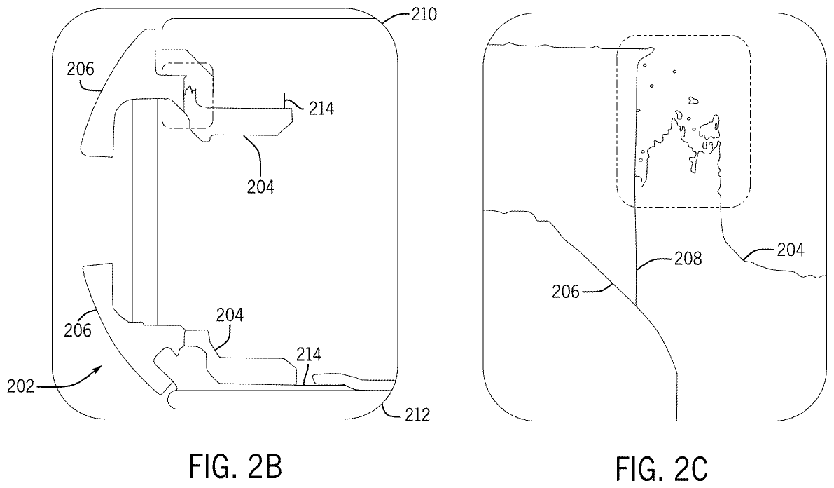

FIG. 2A illustrates a cross sectional view of a portion of an electronic device 200, according to one example. The electronic device 200 can include a housing 202 that includes a clad material having an interior metal 204 disposed within an exterior metal 206. The exterior metal 206 can be different from the interior metal 204. In some examples, the exterior metal 206 can include an alloy that is different from the interior metal 204. In other examples, the exterior metal 206 can include a treatment process (e.g. anodizing, PVD), coating process, (e.g. chemical conversion, painting, powder coating, anodization), or plating process (e.g. chrome, gold, or silver plating) that is not necessarily applied to the interior metal 204. In other examples, the interior metal 204 can include a treatment process or coating process that is not necessarily applied to the exterior metal 206. These corrosion treatment processes are described in greater detail below. In some examples, the exterior metal 206 includes a metal less susceptible to corrosion than the interior metal. In other words, the interior metal 204 can be subjected to galvanic corrosion, causing the interior metal 204 to fissure, erode, or lose strength.

The interior metal 204 and the exterior metal 206 can combine to form a clad material. The interior metal 204 and the exterior metal 206 include an interface where the interior metal 204 and the exterior metal 206 contact. The interface can include a clad interface 208. The clad interface 208 can include a uniform grain structure of the interior metal 204 and the exterior metal 206 and a uniform contact surface. As shown in FIG. 2A, the housing 202 can further include components, operators and/or actuators that are disposed in apertures, orifices, and/or openings extending through the exterior metal 206 and the clad interface 208 into the interior of the electronic device 200. For example, a display 210 or backing 212 of the electronic device 200 (e.g. a screen) can be configured to contact the exterior metal 206 and/or the interior metal 204. The display 210 and/or backing 212 does not require any movement between the housing 202 and the display 210 and/or backing and thus can be sealed with an adhesive 214 at the interface of the housing 202 and the display 210 as well as the interface of the housing 202 and the backing 212. The adhesive 212 can be configured to seal the electronic device 200 and prevent any electrolyte from entering at the interface of the housing 202 and the display 210 and thus prevent any corrosion.

The housing 202 can further include an actuator and/or operator such as a button 216. In some examples, the button 216 can be depressed and/or released. The button 216 of FIG. 2A is shown depressed. To keep the area inside the housing 202, in some examples, an O-ring 218 can be included. The O-ring 218 can be configured to seal the housing 202 and prevent exposure of the interior metal 204 to an electrolyte and prevent galvanic corrosion of the interior metal 204. However, as shown in FIG. 2A, in some embodiments, when the button 216 is depressed, the O-ring 218 is disposed interior to the clad interface 208 and a portion of the interior metal 204 can be exposed to the electrolyte. In some examples, when the button 216 is depressed the area interior to the O-ring 218 remains water tight, but the exposure of the interior metal 204 can cause galvanic corrosion of the housing 202. Other actuators can include at least one of a speaker, and/or a switch. In some examples, the openings can include a receptacle such as a plug disposed therein. In practice, the housing 202 is most susceptible to galvanic corrosion at the interface between the apertures or openings and the actuators (e.g. speakers, plugs, or buttons) which either translate in the aperture and selectively expose the interior metal 204, or remain exposed to receive a plug or other device, thereby leaving the interior metal 204 continually exposed.

FIGS. 2B-2C illustrate a cross sectional view of a portion of the electronic device 200 showing the interior metal 204 susceptible to galvanic corrosion. FIG. 2C is an enlarged portion of FIG. 2B to better illustrate the potential effects of galvanic corrosion on the interior metal 204 when exposed to an electrolyte. Galvanic corrosion, also known as bimetallic corrosion, is an electrochemical process whereby one metal corrodes in preference to another metal that it is in contact with through an electrolyte. Galvanic corrosion occurs when two dissimilar metals are disposed in a conductive solution and are electrically connected. One metal (the cathode, e.g. the exterior metal 206) can be protected, whilst the other (the anode, e.g. the interior metal 204) is subject to corrosion. The rate of attack on the anode can be accelerated, compared to the rate of attack when the metal is uncoupled from the exterior metal 206.

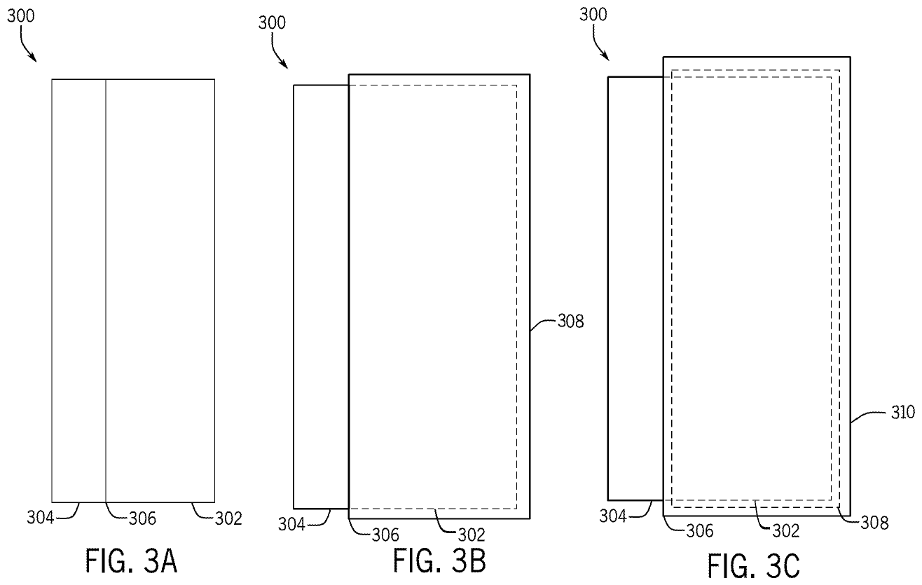

FIG. 3A illustrates a cross sectional view of a clad material 300 having an interior metal 302 disposed within an exterior metal 304, according to one exemplary embodiment. As described briefly above, an advantage of clad material is that the material combines the superior properties of each metal. For example, overall strength, corrosion resistance, weight, cost, thermal conductivity, and electrical conductivity can be improved (relative to single materials on their own) by including a clad material within a housing. As a result, clad products produce a combined material superior to the individual metals taken alone. In some examples, the clad material 300 can be manufactured by roll bonding the interior metal 302 with the exterior metal 304 to produce a metallurgically bonded clad interface 306. Many metals can be combined with this technique to provide a custom metal with specific desired properties. In some embodiments, the exterior metal 304 can include stainless steel or titanium, and the interior metal 302 can include aluminum, aluminum alloys, magnesium, magnesium alloys, beryllium, beryllium alloys, or any other suitable metal.

In some examples, roll bonding can be achieved by processing the interior metal 302 and exterior metal 304 through a conventional plate hot rolling mill that reduces the thickness and metallurgically bonds the interior metal 302 to the exterior metal 304. The clad material 300 can be fabricated into different shapes, which allows designers the freedom to produce a variety of devices (e.g. a housing for an electronic device). Clad material 300 can be cut and formed by most shop operations, which include shearing, plasma cutting, drawing, bending, hot forming, machining, drilling and punching.

FIG. 3B illustrates the clad material 300 of FIG. 3A with a corrosion resistant coating 308 disposed on the interior metal 302. In some examples, the coating 308 can be applied to the interior metal 302 to the clad interface 306 and not be disposed on the exterior metal 304. In other examples, the coating 308 can extend over the clad interface 306 and can be disposed on a portion of both the interior metal 302 and the exterior metal 304.

The corrosion resistant coating 308 can include any coating suitable for preventing and/or reducing galvanic corrosion of the interior metal 302. The coating 308 can include an appropriate thickness to prevent corrosion for the life of the device. A thicker coating may be included to provide additional corrosion protection, while a thin coating may be used and/or preferred for proper tolerances between components of the housing. In some examples, the coating 308 can include a thickness between about 0.5 μm and 20 μm, or between approximately 1 μm and about 10 μm. In some examples, the thickness of the coating can be between about 1 μm and about 2 μm, about 2 μm and about 5 μm, about 5 μm and about 8 μm, or about 8 μm and about 10 μm.

In some examples, the coating 308 is temperature resistant up to about 120° C. or greater. The coating 308 should be able to be applied prior to processes required to improve the properties of the exterior metal 304 or other components of the housing. In some examples, the coating 308 includes a vapor deposition. Several different coating deposition processes either associated with physical vapor deposition (PVD), chemical vapor deposition (CVD), or hybrid PVD+CVD technology can be used for deposition of the coating 308.

PVD Coating refers to a variety of thin film deposition techniques where a solid material is vaporized in a vacuum environment and deposited on substrates as a pure material or alloy composition coating. As PVD transfers the coating material as a single atom or on the molecular level, it can provide a pure and high performance coating. The two most common PVD coating processes are sputtering and thermal evaporation. Sputtering involves the bombardment of the coating material with a high energy electrical charge causing it to “sputter” off atoms or molecules that are deposited on the substrate (e.g., interior metal 302). Thermal evaporation involves elevating a coating material to its boiling point in a high vacuum environment causing a vapor stream to rise in the vacuum chamber and then condense on the substrate.

CVD Coating can be formed and/or deposited by a broad range of thin film deposition techniques. CVD can produce high quality, high-performance solid coatings or polymers. While there are a wide variety of specific CVD processes, what they all have in common is a chemical reaction of a gaseous chemical precursor driven by either heat or plasma to produce dense thin films on a substrate. CVD is a versatile and fast method of growing dense and chemically pure coatings having uniform thicknesses. For thermal CVD, the substrate can be heated and a precursor reactant gas is introduced into the deposition chamber which may either be directly absorbed onto the surface of the substrate to be coated, or may form an intermediate reactant in the gas phase, which is then deposited onto the substrate. Similar to PVD, the CVD processes can be run at elevated temperatures and at atmospheric or lower pressures.

Both CVD and Physical Vapor Deposition (PVD) processes are similar in that they are used to create thin films on an atomic or molecular level of very high purity and density. However, what defines CVD is the chemical reaction that occurs on the surface of the substrate. It is this chemical reaction that distinguishes it from PVD sputtering or thermal evaporation thin film deposition processes that usually don't involve chemical reactions. Another key difference is that the deposition of CVD coating is in a flowing gaseous state which is a diffuse multidirectional type of deposition. PVD on the other hand involves vaporizing solid physical particles into a plasma which is a line-of-site deposition.

CVD offers a wide variety of coating materials based on metals, alloys and ceramics. The chemical reactions that characterize CVD can also be used to form alloys. CVD deposits very pure films, over 99.995% purity. However, in some examples, thermal CVD processes are heat driven which can affect the type of substrate or interior metal that can be coated.

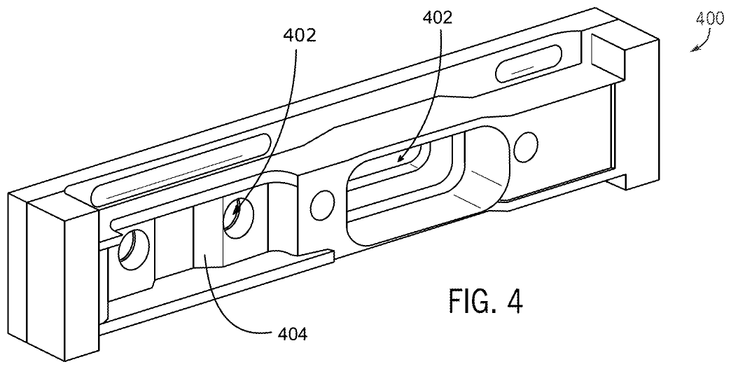

In some examples, the coating 308 can include a parylene coating. In some examples, parylene can be applied as vapor. The coating layer 308 can conform to complex shapes and provides complete and even coverage, and has a generally high dielectric strength (relative to epoxy, silicones, and urethane coatings). Parylene is a superior barrier layer that provides protection from moisture, corrosion, salt spray and/or solvents. Parylene is chemically inert, ultra-thin, and conforms to components evenly and consistently. In some examples, parylene can be applied as a chemical deposition process. During this process, parylene deposits molecule by molecule onto parts placed in a vacuum chamber. This process creates an extremely conformal coating that evenly covers grooves, crevices, gaps, and sharp points. Because the coating is applied molecule by molecule, the thickness of the coating 308 can be well controlled. As will be described below with reference to FIG. 4, the interior metal 302 can have a complex shape including orifices and steps that is well suited to being coated according to the processes described herein.

In some examples, the corrosion resistant coating can include an electrophoretic deposition. Electrophoretic deposition (EPD) is a method of producing coatings or films on electrically conducting materials. In some examples, the EPD includes a migration of electrically charged particles in a liquid toward an electrode under the influence of an electric current. The particles suspended in a liquid have a positive or negative electric charge. When a direct current is applied across the suspension liquid with electrodes, the suspended particles move toward the electrode with the opposite charge. EPD can be performed by using the interior metal 302 as an electrode onto which oppositely charged particles are deposited, forming a layer. Depending on whether the positive or negative electrode is used, the process might be referred to as anodic or cathodic electrodeposition, respectively.

In some examples, the corrosion resistant coating 308 can include an anodized coating. In some examples, the interior metal 302 can be anodized to yield a wide range of durable finishes, which resist degradation. In some examples, a positive potential can be applied to the interior metal 302 to promote an oxide growth and form an aluminum oxide when the interior metal 302 includes aluminum. In other words, an anodized layer can result from an electrochemical anodization process of aluminum or an aluminum alloy. In some examples, an aluminum or carbon counter-electrode can be utilized. In an example, anodizing the surface of the interior metal 302 can include applying a 15V potential to the surface. In particular, during the electrolytic anodizing process, a portion of the interior metal 302 can be converted or consumed by the conversion to the anodized layer. In some embodiments, the anodization can form a thick protection layer of oxide. The anodized layer can have sufficient hardness such that the anodized layer functions as a protective coating to protect the interior metal 302.

In some examples, the corrosion resistant coating 308 can include a polyurethane. Polyurethane is a substance that is, in most cases, a thermosetting polymer that will not melt when heated. When applied in a thin film, once it cures, it forms a powerful and durable barrier for the underlying interior metal 302. In some examples, Polyurethane's hard and non-toxic ingredients make it a strong adhesive that can hold out against impact, moisture, and the elements. Additionally, it is also highly resistant to alcohol and chemical formulations.

In some examples, the interior metal 302 can be pre-treated prior to the application of the polyurethane coating. In some examples, the interior metal 302 can be treated with a hot water treatment. The hot water can provide better adhesion for the polyurethane coating. In other examples, the interior metal 302 can be anodized prior to the application of polyurethane to improve adhesion. The polyurethane coating can include a thickness between about 0.5 μm and 20 μm, or more particularly, between about 1 μm and about 10 μm, and can be applied in any suitable manner. In some examples, the interior metal 302 can be dip coated or powder coated. In other examples, the corrosion resistant coating 308 can include a vapor deposition polymerization process. Chemical vapor deposition (CVD) polymerization utilizes the delivery of vapor-phase monomers to form chemically well-defined polymeric films. Polyurethane can be applied via CVD polymerization, in the same process as described above with reference to parylene. In some examples, multiple processes and/or corrosion resistant coatings can be applied to the interior metal 302.

FIG. 3C illustrates clad material of FIG. 3A with a first corrosion resistant coating and a second corrosion resistant coating disposed on the interior metal. In some examples, the corrosion resistant coating 308 can be a first coating. A second coating 310 can be applied over the first coating to either improve corrosion resistance, achieve appropriate coating thickness, or impart another desired property. In some examples, the second coating 310 can be applied to at least a portion of the interior metal 302. In some examples, the first coating 308 and the second coating 310 can include different compositions. For example, the first coating 308 can include an anodization layer and the second coating can include a polyurethane. In other examples, the first coating 308 and the second coating 310 can be the same composition (e.g., parylene).

In some examples, a first component of the housing can by protected from galvanic corrosion differently than a second component. The coating of the interior metal can involve processes that are more or less expensive and/or time consuming than others, depending on the susceptibility of the component and/or the desired level of protection. In some examples, a corrosion resistant coating can be applied using the methodologies detailed herein due to the complexity of the component. FIG. 4 illustrates an example clad structure having a complicated geometry—such as an intricate stepped 404, tortuous, irregular, angular, undulating, or buck polynomial based surface. Additionally, the clad structure can include cut-outs, overhangs, blind features, and at least one aperture 402 defined by at least the interior metal. For components of higher complexity, methods of application of the corrosion resistant coating may vary. Particularly, CVD and other vapor deposition based processes are particularly suited to coat the often complex geometries of the interior metal with a consistent thickness of protective material, such as parylene or a polyurethane based material having a thickness between about 0.5 μm and 20 μm, or between approximately 1 μm and about 10 μm. Additionally, using these methods, the exterior metal 304, or selective portions of the exterior metal, can be selectively masked and left without the protective coating. Regardless of the configuration, each of the methods disclosed herein can be configured to minimize and/or prevent galvanic corrosion of the interior metal. The corrosion resistant coating ensures the interior metal (e.g., interior metal 302) is not directly exposed to an electrolyte. Rather, the interior metal remains within the watertight portion of the housing and is protected by the exterior metal. Any of the housings, coatings, and/or clad material systems discussed above with reference to FIGS. 2A-4 can be included in the housing alone or in combination to eliminate galvanic corrosion.

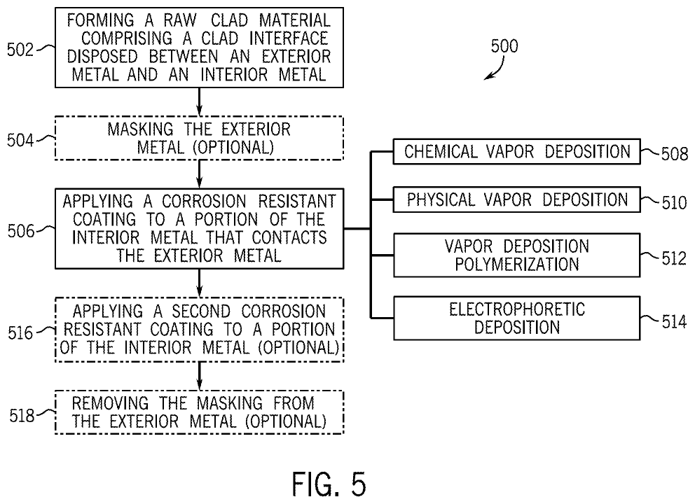

FIG. 5 illustrates a method 500 of forming a protective interface in a clad housing, according to one example. In some examples, the method 500 can include forming a raw clad material as shown in block 502. The raw clad material can be formed by roll bonding, press fitting, extrusion, or any other suitable method known in the art. In some embodiments, the raw clad material can include an interior metal disposed within an exterior metal. In some embodiments, the clad material can be pre-formed such that the clad housing includes a clad interface disposed between the exterior metal and the interior metal. The exterior metal can include an outer surface and an inner surface.

The method 500 can include applying a corrosion resistant coating to at least a portion of the interior metal that contacts the exterior metal, as shown in block 506. In some examples, applying a corrosion resistant coating includes a chemical vapor deposition process 508 as described above in reference to FIG. 3B. In other examples, applying a corrosion resistant coating includes a physical vapor deposition process 510, a vapor deposition polymerization process 512, and/or an electrophoretic deposition process 514.

The application of the corrosion resistant coating can include at least one of the deposition processes, but can also include a first process followed by a second process. As shown in block 516, the method 500 can include applying a second corrosion resistant coating to a portion of the interior metal. For example, applying a corrosion resistant coating can include performing a physical deposition process on the interior metal and then conducting a chemical deposition process on the interior metal. In some examples, the first coating and the second coating can include different compositions, can overlap, can be formed on disparate portions of the interior metal, or can be combinations thereof.

In some examples, the method 500 can include masking the exterior metal, as shown in block 504, prior to applying the corrosion resistant coating to the interior metal. In some examples, masking the exterior metal includes applying a removable coating to all or only selective portions of the exterior metal. The masking of the exterior metal ensures that any coating applied to the clad material where the coating is not desired can be removed during the application of the coating. In some examples, masking of the exterior metal can include forming a pattern on the exterior metal and/or interior metal. In some examples, the mask can include a resin film. In other embodiments, the mask can include a polyethylene terephthalate (PET) or polyimide having a thickness of about 10 μm to 30 μm and selectively applied to the portions of the exterior metal where no corrosion resistant coating is desired. In some examples, the corrosion resistant coating is applied to the entirety of the interior metal, and to eliminate any opportunity for exposure to the electrolyte, the corrosion resistant coating can extend slightly past the clad interface and onto the exterior metal. In this manner, the interior metal can be encapsulated from exposure to the electrolyte. Alternatively, only a portion of the interior metal that is most likely to be exposed to the electrolyte is covered by the corrosion resistant coating, such as in the inner surface of a button hole or cavity.

In some examples, the method 500 can include removing the masking from the exterior metal, as shown in block 518. The masking can be removed by any suitable method. In some examples, the masking can be removed prior to applying a second corrosion resistant coating to a portion of the interior metal. In other examples, the masking can be removed after applying a second corrosion resistant coating to a portion of the interior metal. In other examples, the masking can be removed after assembly of the housing and/or components or can remain without removal, as directed by the manufacturing process. Upon completion of the exemplary method, the clad part can be assembled to an electronic device and can be mated with any number of switches, buttons, and other components, while reducing or eliminating the possibility of galvanic corrosion.

In some examples, personal information or data may be used. In those examples, the personal information or data should be received, stored, used, accessed and/or distributed in accordance well recognized and accepted standards and protocols.

The foregoing description, includes specific nomenclature to provide a thorough understanding of the various examples. However, the specific details provided herein are not necessary to practice the described examples. Rather, the foregoing descriptions are presented for purposes of illustration and description and are not intended to be exhaustive or to limit the embodiments to the precise forms disclosed.

What is claimed is:

1. A housing for an electronic device, comprising:
a clad comprising an interior metal and an exterior metal, the exterior metal being different than the interior metal, and the interior metal and the exterior metal being joined at a clad interface, the exterior metal comprising a lower electrical conductivity than the interior metal;
the housing defining an aperture extending through the exterior metal and the clad interface;
an actuator or a plug disposed within the aperture; and
a corrosion resistant coating disposed on a portion of the interior metal at the clad interface, the coating comprising a thickness between about 1 μm and about 10 μm.

2. The housing of claim 1, wherein the actuator comprises at least one of a button, a speaker, or a switch.

3. The housing of claim 1, wherein:
the exterior metal comprises stainless steel or titanium; and
the interior metal comprises aluminum.

4. The housing of claim 1, wherein the exterior metal is substantially free of the corrosion resistant coating.

5. The housing of claim 1, wherein the corrosion resistant coating comprises an electrophoretic deposition.

6. The housing of claim 1, wherein the corrosion resistant coating comprises a vapor deposition.

7. The housing of claim 1, wherein the corrosion resistant coating comprises parylene.

8. A method of forming a protective interface in a clad housing, the clad housing including an exterior metal defining an exterior surface and an interior metal defining an interior surface, the exterior metal and the interior metal joined at a clad interface, the method comprising:
masking a portion of the exterior metal; and
applying a corrosion resistant coating to a portion of the interior metal and a portion of the clad interface.

9. The method of claim 8, wherein applying the corrosion resistant coating comprises a chemical vapor deposition process.

10. The method of claim 8, wherein applying a corrosion resistant coating comprises a physical vapor deposition process.

11. The method of claim 8, wherein applying a corrosion resistant coating comprises a vapor deposition polymerization process.

12. The method of claim 8, wherein:
the exterior metal comprises at least one of stainless steel or titanium;
the interior metal comprises aluminum; and
the corrosion resistant coating comprises at least one of parylene or a polyurethane.

13. The method of claim 8, wherein:
the corrosion resistant coating comprises a first coating; and
the method further comprises applying a second coating to at least a portion of the interior metal.

14. The method of claim 13, wherein the first coating and the second coating comprise different compositions.

15. The method of claim 8, wherein masking a portion of the exterior metal comprises masking the exterior surface prior to the application of a corrosion resistant coating.

16. The method of claim 15, wherein masking the exterior metal comprises applying a removable coating to the exterior metal.

17. A system configured to prevent galvanic corrosion of a housing for an electronic device, comprising:
a clad structure comprising an exterior metal and an interior metal joined at an interface, the exterior metal comprising a lower electrical conductivity than the interior metal, the housing defining an orifice extending through the exterior metal and the interface; and
a corrosion resistant coating disposed on the interior metal;
wherein the exterior metal is substantially free of the corrosion resistant coating.

18. The system of claim 17, wherein the corrosion resistant coating is temperature resistant up to about 120° C.

19. The system of claim 17, wherein:
the corrosion resistant coating comprises a thickness between about 1 μm and about 10 μm; and
the interior metal defines at least one of a cut-out, an overhang, or an aperture.

20. The system of claim 17, wherein the coating comprises at least one of parylene or a polyurethane.
